(19) United States
(12) Patent Application Publication
(10) Pub. No.: US 2025/0029880 A1
(43) Pub. Date: Jan. 23, 2025

(54) Seal Ring Structure with Alignment Mark

(71) Applicant: Taiwan Semiconductor Manufacturing Company, Ltd., Hsin-Chu (TW)

(72) Inventor: Szu-Ling Liu, Hsinchu City (TW)

(21) Appl. No.: 18/354,398

(22) Filed: Jul. 18, 2023

(51) Int. Cl. H01L 23/10; H01L 23/00; H01L 23/58

(52) U.S. Cl. CPC H01L 23/10; H01L 23/564; H01L 23/585; H01L 23/544; H01L 2223/54426

(57) ABSTRACT

Seal ring structures having alignment marks are disclosed herein. An exemplary semiconductor structure includes a seal ring surrounding a circuit region and a corner seal ring (CSR) structure at an interior corner of the seal ring. The CSR structure includes a bridge section between a first edge and a second edge of the seal ring, an L-shaped section between the seal ring and the bridge section and between the first edge and the second edge of the seal ring, a first area between the seal ring and the L-shaped section, and a second area between the L-shaped section and the bridge section. The seal ring includes a first top metal line and an aluminum pad (AP) disposed over and connected to the first top metal line. The L-shaped section includes a second top metal line having an L-shape. The first area and the second area are free of dummy AP.

### BACKGROUND

In semiconductor technologies, a semiconductor wafer is processed through various fabrication steps to form integrated circuits (IC). Typically, several circuits or IC dies are formed onto the same semiconductor wafer. The wafer is then diced to cut out the circuits formed thereon. To protect the circuits from moisture degradation, ionic contamination, and dicing processes, a seal ring is formed around each IC die. This seal ring is formed during fabrication of the many layers that comprise the circuits, including both the front-end-of-line (FEOL) processing and back-end-of-line processing (BEOL). The FEOL includes forming transistors, capacitors, diodes, and/or resistors onto the semiconductor substrate. The BEOL includes forming metal layer interconnects and vias that provide routing to the components of the FEOL. Additionally, alignment marks, such as laser fuse marks and other marks, may also be formed on chips and used for alignment and monitoring by a tool, such as a laser-fuse tester during a chip probing stage. Unhealthy processes may damage these alignment marks, which may impact assembly alignment in subsequent processes.

Although existing seal ring structures and alignment marks have been generally adequate for their intended purposes, improvements are desired. For example, it is desired to form certain seal rings with alignment marks that are robust and stay undamaged through the processes.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a fragmentary top plan view of an exemplary semiconductor structure with a circuit region and a seal ring showing alignment marks according to various aspects of the present disclosure.

FIGS. 2A, 3A, 4A, 5A, 6A, 7, 8, and 9 are fragmentary top plan views of an area A of the semiconductor structure in FIG. 1 according to various aspects of the present disclosure.

FIGS. 2B, 3B, 4B, 5B, and 6B are fragmentary cross-sectional views of a portion of the semiconductor structure along a B-B line in FIGS. 2A, 3A, 4A, 5A, and 6A, respectively, according to various aspects of the present disclosure.

FIGS. 2C, 3C, 4C, 5C, and 6C are fragmentary cross-sectional views of a portion of the semiconductor structure along line C-C in FIGS. 2A, 3A, 4A, 5A, and 6A, respectively, according to various aspects of the present disclosure.

### DETAILED DESCRIPTION

The present disclosure relates generally to semiconductor structures, and more particularly, to semiconductor structures having seal ring structures.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Furthermore, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

A semiconductor structure, such as an integrated circuit (IC) chip, includes a circuit region (or circuit area, chip area, device region, chip die) surrounded by a seal ring region. The seal ring region provides protection to the integrated circuit in the circuit region from various environment damages, such as moisture and chemicals. A seal ring structure in the seal ring region includes multiple layers vertically extending from the substrate, through an interconnect structure, and up to a passivation layer. The seal ring structure may be formed simultaneously with the circuit features in the circuit region through various fabrication stages, such as with front-end-of-line (FEOL) structures, middle-end-of-line (MEOL) structures, and/or back-end-of-line (BEOL) structures. As used herein, FEOL structures include structural features of transistors or other semiconductor devices fabricated on a semiconductor substrate; MEOL structures include source/drain contact vias or gate contact vias; and BEOL structures include interconnect structures and passivation structures over the interconnect structures. In the BEOL processes, conductive lines or vias are formed in multiple metal layers stacked over the semiconductor substrate to connect various features in the circuit region. Simultaneously, conductive lines and vias are formed in the seal ring region of each metal layer. Components in the seal ring region, such as transistors, conductive lines, and vias, do not provide electrical functions for the semiconductor structure as their counterparts in the circuit region do. Instead, the components in the seal ring region enclose and protect the circuit region from moisture, mechanical stress, or other defect-generating mechanisms.

A conductive pad (e.g., an aluminum pad, also referred to as an AP) may be formed over a top metal layer in the seal ring region. The conductive pad may be surrounded by a non-conductive material, which helps to insulate the conductive pad from other components of the IC device. The conductive pad may be connected to the top metal layer by vias and be referred to as a non-dummy conductive pad. In some other cases, the conductive pad is not connected to the top metal layer and is referred to as a dummy conductive pad. The conductive pad may be used for stress release and/or as an alignment mark. Improper designs and/or fabrication process (e.g., an etching process) may cause various defects in the conductive pad. For example, a portion of a conductive pad is not formed, or a dummy conductive pad is connected to an adjacent non-dummy conductive pad. Such defects may reduce stress release capability and impact identification of the alignment mark during assembly alignment, which may cause further defects and impact the overall performance of the IC device.

The present disclosure thus proposes a semiconductor structure having a seal ring region that eliminates patterns of dummy conductive pads (e.g., dummy APs) over top metal lines. In the present disclosure, the semiconductor structure includes a seal ring region surrounding a circuit region (or an IC area or a chip area) and over a substrate. The seal ring region includes stacks of metal layers over the substrate. The semiconductor structure includes a seal ring disposed in the seal ring region and corner seal ring (CSR) structures disposed at interior corners of the seal ring. The seal ring includes an AP over a top metal line of the seal ring. The CSR structures each includes a bridge section extending between a first edge and a second edge of the seal ring and an L-shaped section disposed between the seal ring and the bridge section. The L-shaped section includes an alignment mark. A first area between the L-shaped section and the seal ring and a second area between the L-shaped section and the bridge section are free of dummy AP. Because CSR structures in the seal ring region in the present disclosure do not include dummy AP patterns, defects are reduced and/or eliminated in portions of the seal region that include the CSR structures. Thus, impact of damaged dummy APs in the CSR structure areas on alignment is substantially reduced or eliminated. The semiconductor structure may be diced (or cut) outside of the seal ring region, and the seal ring region can provide fully enclosed protection to the circuit region.

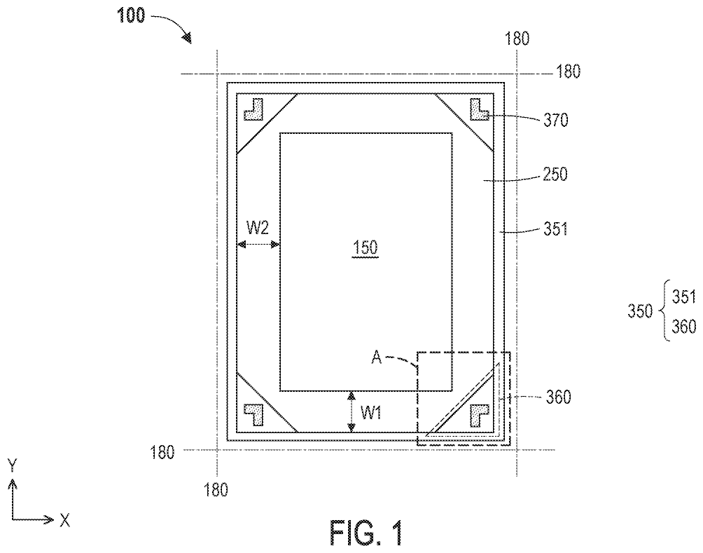

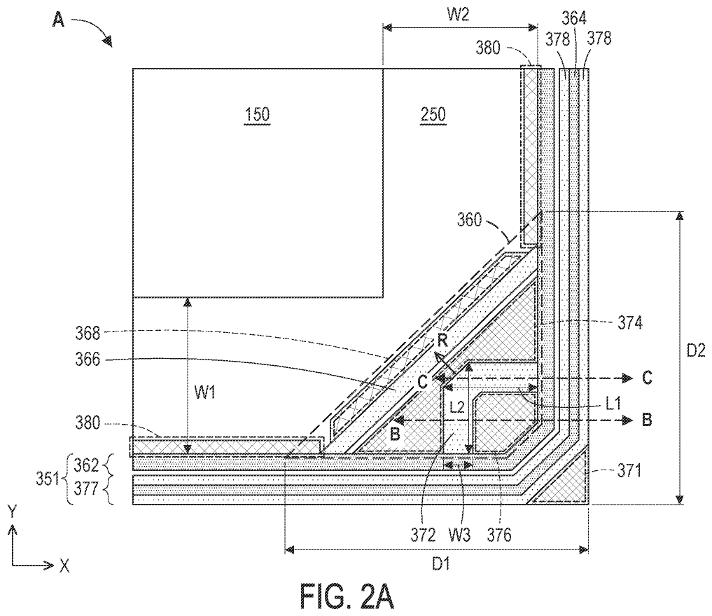

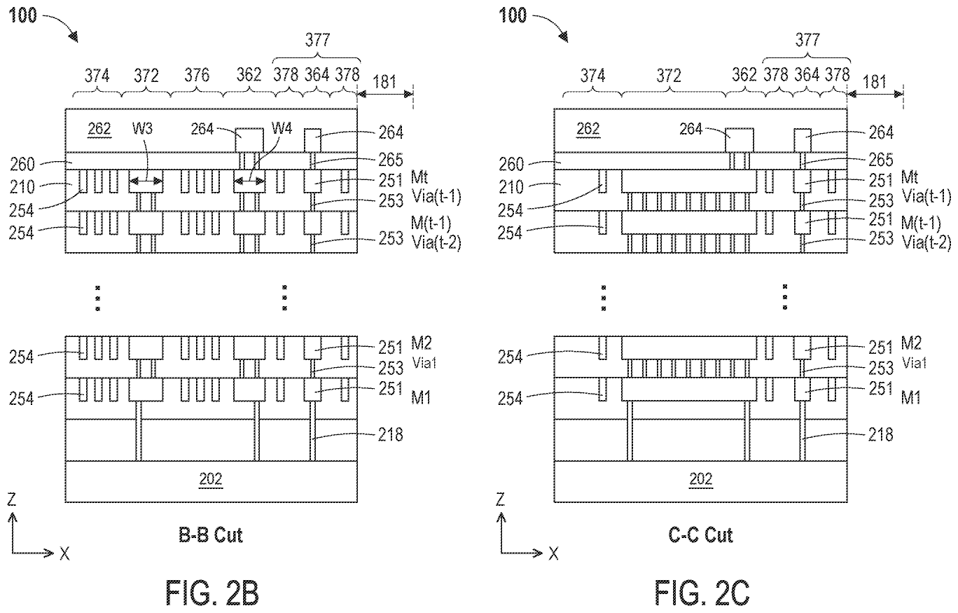

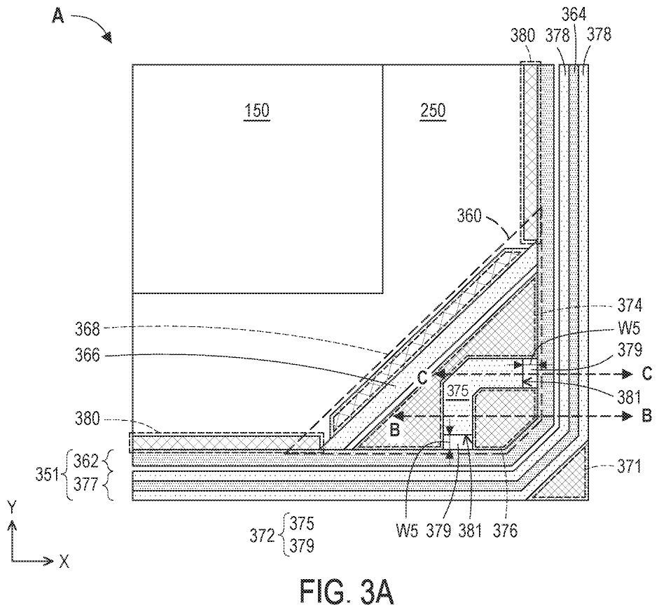

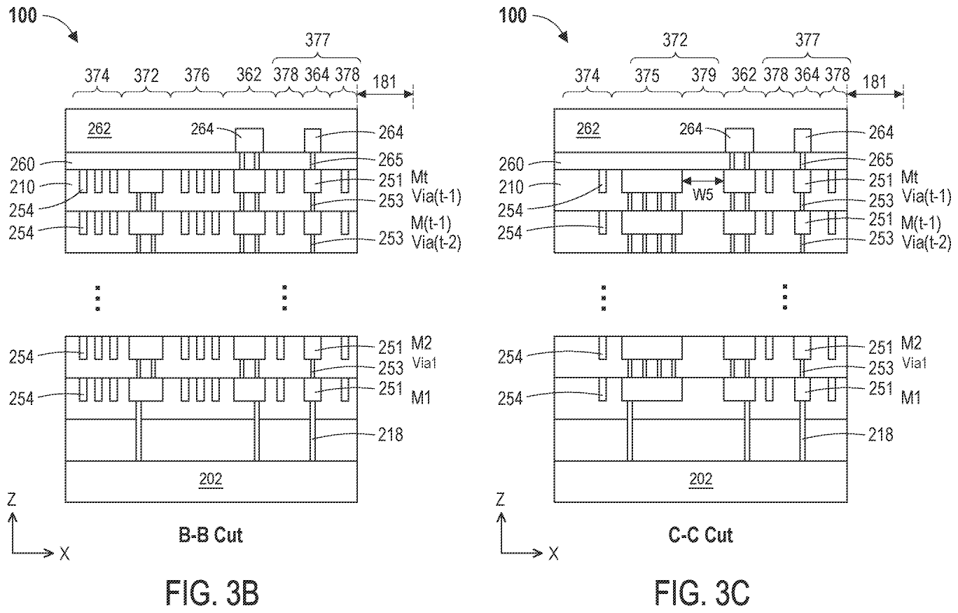

FIG. 1 is a fragmentary top plan view of a semiconductor structure 100 having a circuit region 150 and a seal ring region 350 having alignment marks 370 according to various aspects of the present disclosure. FIG. 2A is a fragmentary top plan view of an area A of the semiconductor structure 100 in FIG. 1 according to various aspects of the present disclosure. FIGS. 2B and 2C are fragmentary cross-sectional views along line B-B and line C-C, respectively, of the semiconductor structure 100 in FIG. 2A according to various aspects of the present disclosure. FIGS. 3A, 4A, 5A, 6A, 7, 8, and 9 are fragmentary top plan views of the area A of the semiconductor structure 100 in FIG. 1 according to various alternative aspects of the present disclosure. FIGS. 3B, 4B, 5B, and 6B are fragmentary cross-sectional views along the B-B line of the semiconductor structure 100 in FIGS. 3A, 4A, 5A, and 6A, respectively, according to various aspects of the present disclosure. FIGS. 3C, 4C, 5C, and 6C are fragmentary cross-sectional views along the C-C line of the semiconductor structure 100 in FIGS. 3A, 4A, 5A, and 6A, respectively, according to various aspects of the present disclosure.

Referring to FIG. 1, the semiconductor structure 100 (such as a manufactured wafer or a part thereof) includes the seal ring region 350 that encloses (or surrounds) the circuit region 150. The depicted embodiment shows that one seal ring region 350 encloses one circuit region 150. In other embodiments (not shown), the seal ring region 350 may enclose more than one circuit region 150. The circuit region 150 may be a memory chip or a processor chip. For example, the circuit region 150 may be a transmitter chip (such as a wireless transmitter) or a receiver chip (such as a wireless receiver). The circuit region 150 may include planar transistors, or multi-gate transistors, such as fin FETs (FinFETs) or multiple-channel-stacked FETs. In some examples, the multiple-channel-stacked FETs include gate-all-around (GAA) FETs. In the depicted embodiment, the circuit region 150 is produced as an individual die or chip. For example, the semiconductor structure 100 is diced (or cut) along scribe lines 180 as illustrated in FIG. 1. The seal ring region 350 can stay intact during the dicing process and provide scaling and protective functions to the circuit region 150.

Still referring to FIG. 1, the semiconductor structure 100 includes a seal ring 351 having a rectangular periphery (i.e., its exterior outline is rectangular or substantially rectangular) and four corner seal ring (CSR) structures 360 at four interior corners of the rectangular periphery. The seal ring 351 and the four CSR structures 360 are disposed in the seal ring region 350. The CSR structures 360 are triangular shaped or substantially triangular shaped for various mechanical concerns. For example, the periphery of each CSR structure 360 is substantially a right triangle or a right isosceles triangle. The legs of the triangle can run parallel to the edges of the periphery of the seal ring 351, and the hypotenuse of the triangle can be arranged adjacent to a corner of the circuit region 150. The CSR structures 360 provide various mechanical benefits to the seal ring 351, such as preventing layer peeling at the corner of the chips during dicing processes. With the CSR structures 360, the interior outline (or interior boundary) of the seal ring region 350 is octagonal or substantially octagonal. In some embodiments, each CSR structure 360 includes an alignment mark 370. The alignment mark 370 may be used during an assembly alignment process to increase accuracy during the dicing process by which the circuit region 150 is separated from the rest of the semiconductor structure 100.

In embodiments, the semiconductor structure 100 includes an assembly isolation region 250 between the circuit region 150 and the seal ring region 350, where no circuit elements or seal ring structures exist. The assembly isolation region 250 includes an isolation structure (such as shallow trench isolation). The isolation structure may include silicon oxide, silicon nitride, silicon oxynitride, other suitable isolation material (for example, including silicon, oxygen, nitrogen, carbon, or other suitable isolation constituent), or combinations thereof. The isolation structure can include different structures, such as shallow trench isolation (STI) structures and/or deep trench isolation (DTI) structures. In some embodiments, the semiconductor structure 100 includes various dielectric layers (e.g., an interlayer dielectric (ILD) layer, a contact etch-stop layer (CESL)) over the isolation structures. The ILD layer includes a dielectric material, such as tetraethylorthosilicate (TEOS), silicon oxide, a low-k dielectric material, doped silicon oxide such as borophosphosilicate glass (BPSG), phosphosilicate glass (PSG), FSG, boron doped silicate glass (BSG), other suitable dielectric materials, or combinations thereof. The ILD layer may include a multi-layer structure having multiple dielectric materials and may be formed by a deposition process such as, for example, CVD, FCVD, SOG, other suitable methods, or combinations thereof. The CESL may comprise silicon nitride, silicon oxynitride, silicon nitride with oxygen or carbon elements, other suitable materials, or combinations thereof, and may be formed by CVD, PVD, ALD, other suitable methods, or combinations thereof. The ILD layer may be deposited after the deposition of the CESL. In some embodiments, the semiconductor structure 100 may include various dummy lines and dummy vias in the assembly isolation region 250. Widths of the assembly isolation region 250 may include a dimension W1 along “Y” direction for the top and bottom portions of assembly isolation region 250 and a dimension W2 along “X” direction for the left and right portions of assembly isolation region 250. In an embodiment, a width of the assembly isolation region 250 (e.g., dimension W1 and/or dimension W2) is about 30 μm to about 100 μm. If the width is too large, it may unnecessarily increase the footprint of the IC chip and the costs associated therewith. If the width is too small, the isolation between the circuit region 150 and the seal ring region 350 may not be enough.

Referring to FIG. 2A, in some embodiments, the CSR structure 360 includes a bridge section 366, an L-shaped section 372, a first area 376 between the seal ring 351 and the L-shaped section 372, and a second area 374 between the L-shaped section 372 and the bridge section 366. The bridge section 366 includes a continuous linear feature and extends between a first edge (e.g., a side portion) and a second edge (e.g., a bottom portion) of the seal ring 351. The L-shaped section 372 is disposed between the seal ring 351 and the bridge section 366 and extends between the first edge and the second edge of the seal ring 351. The L-shaped section 372 has an “L” shape and includes the alignment mark 370. In some embodiments, such as the depicted embodiment in FIG. 2A, from a top view, an entirety of the L-shaped section 372 can be used as the alignment mark 370. In other embodiments (to be described below), a portion of the L-shaped section 372 from a top view can be used as the alignment mark 370. Thus, the alignment mark 370 is within boundaries of the L-shaped section 372 from a top view. In the depicted CSR structure 360, the L-shaped section 372 includes a top portion, a side portion, and a sloped portion extending between the top portion and the side portion. In the depicted embodiments in FIG. 2A, both the L-shaped section 372 and bridge section 366 are connected to the seal ring 351. In some embodiments, to the interior (i.e., the side closer to the circuit region 150) of the seal ring 351, the CSR structure 360 further includes an interior linear structure 380 that has a linear or substantially linear shape. In some embodiments, to the interior of the bridge section 366, the CSR structure 360 further includes an interior linear structure 368 that has a linear or substantially linear shape.

Each of the interior linear structure 380, interior linear structure 368, the first area 376, and the second area 374 includes multiple discrete features.

In some embodiments, the seal ring 351 includes one or more sub seal rings, for example, a first sub seal ring 362 and a second sub seal ring 377 surrounding the first sub seal ring 362. The sub seal rings are concentric to each other. In some embodiments, the sub seal ring 362 is wider than the other sub seal ring(s) (e.g., the sub seal ring 377), thus may be referred to as the main sub seal ring. Having multiple nested sub seal rings ensures that at least the inner sub seal ring(s) is/are protected from cracks during dicing (e.g., die sawing). For example, the sub seal ring 377 can protect the sub seal ring 362 from damages that may occur during dicing. For the sub seal rings 362 and 377 as depicted in FIG. 2A, the bottom portion and the side portion of each sub seal ring are connected by a sloped portion of the respective sub seal ring. In the depicted embodiment, the second sub seal ring 377 includes two dummy metal sections 378 and an AP section 364 disposed between the two dummy metal sections 378. In other embodiments, the second sub seal ring 377 includes the AP section and one dummy metal section 378 disposed between the first sub seal ring 362 and the AP section 364. In yet other embodiments, the second sub seal ring 377 includes the AP section 364 only. The AP section 364 and the dummy metal section(s) 378 each includes a bottom portion and a side portion connected by a sloped portion.

In some embodiments, the seal ring 351 further includes an exterior corner structure 371 which includes multiple discrete features that form a triangular or substantially triangular shape. The exterior corner structure 371 is disposed next to the sloped portion of the second sub seal ring 377. The exterior corner structure 371 and the bottom portion and the side portion of the second sub seal ring 377 form a right angle or an approximately right angle.

The multiple discrete features of the interior linear structure 380, interior linear structure 368, the first area 376, the second area 374, and the exterior corner structure 371 may include stacks of dummy metal lines and/or metal vias (to be described below).

As depicted in FIG. 2A, a distance between a bottom left corner of the CSR structure 360 and a side portion of an exterior outline (or exterior boundary) of the seal ring 351 is D1 along the X direction, and a distance between a top corner of the CSR structure 360 and a bottom portion of the exterior outline of the seal ring 351 is D2 along the Y direction. In some embodiments, D1 is about 70 μm to about 90 μm. In some embodiments, D2 is about 70 μm to about 90 μm. If the distances D1 and/or D2 are too large, area of the CSR structure 360 may be too large, thus available area for the circuit region 150 may be too small, and some mechanical benefits provided by the CSR structure 360 to the seal ring 351 may be reduced. If the distances D1 and/or D2 are too small, some mechanical benefits provided by the CSR structure 360 to the seal ring 351 may be reduced. In some embodiments, D1 is about the same as D2. In some embodiments, a ratio of D1 to D2 is about 0.6 to about 1.7. In some embodiments, a first length of the L-shaped section 372 along the X direction is L1, and a second length of the L-shaped section 372 along the Y direction is L2. In some embodiments, LI is about 20 μm to about 30 μm. In some embodiments, L2 is about 20 μm to about 30 μm. If the lengths L1 and/or L2 are too large, the CSR structure 360 may accordingly be too large, thus available arca for the circuit region 150 may be too small, and some mechanical benefits provided by the CSR structure 360 to the seal ring 351 may be reduced. If the lengths L1 and/or L2 are too small, the L-shaped section 372 may be too small to be identified during an assembly alignment process, and some mechanical benefits provided by the CSR structure 360 to the seal ring 351 may be reduced. In some embodiments, a ratio of L1 to L2 is about 0.5 to about 2. In some embodiments, L1 is about the same as L2.

Referring to FIG. 2B, the semiconductor structure 100 includes a substrate 202. The substrate 202 is a silicon substrate in the present embodiment. The substrate 202 may alternatively include other semiconductor materials in various embodiments, such as germanium, silicon carbide, gallium arsenide, gallium phosphide, indium phosphide, indium arsenide, indium antimonide, SiGe, GaAsP, AlInAs, AlGaAs, GalnAs, GalnP, GaInAsP, or combinations thereof. The substrate 202 may include doped active regions such as a P-well and/or an N-well. The substrate 202 may also further include other features such as a buried layer, and/or an epitaxy layer. Furthermore, the substrate 202 may be a semiconductor on insulator such as silicon on insulator (SOI). In other embodiments, the substrate 202 may include a doped epitaxy layer, a gradient semiconductor layer, and/or may further include a semiconductor layer overlying another semiconductor layer of a different type such as a silicon layer on a silicon germanium layer. The substrate 202 may include active regions (such as N⁺ or P⁺ doped regions) that are configured as an NMOS device (e.g., nFET) or a PMOS device (e.g., pFET). The substrate 202 may include underlying layers, devices, junctions, and other features (not shown). The seal ring region 350, the assembly isolation region 250, and the circuit region 150 are built in or on the substrate 202. The substrate 202 further includes scribe line regions 181 (for the scribe lines 180) surrounding the seal ring region 350.

In some embodiments, the L-shaped section 372, the first sub seal ring 362, and the second sub seal ring 377 each includes one or more conductive features 218 disposed on the substrate 202, such as disposed on active regions of the substrate 202. Numbers of the conductive features 218 in FIGS. 2B and 2C are for examples only and may be any suitable numbers. The conductive features 218 may include multiple conductors vertically stacked, and may include doped semiconductors, metals, conductive nitride, conductive oxide, or other types of conductive materials. Over the conductive features 218, each of the L-shaped section 372, the first sub seal ring 362, and the second sub seal ring 377 further includes a stack of metal lines 251 and metal vias 253, in which multiple metal lines 251 are stacked one over another and vertically connected by the metal vias 253. Although not shown, the bridge section 366 also includes a stack of metal lines 251 and metal vias 253 disposed over the substrate 202 and the conductive features 218.

The metal lines 251 are disposed in a first metal layer (M1) through a top metal layer (Mt). The metal vias 253 are disposed in a first via layer (Vial) through a top via layer (Via(t-1)). For the purpose of simplicity, the metal layers and metal vias between the second metal layer (M2) and the via layer Via(t-2) are not depicted in FIGS. 2B and 2C. Numbers of the metal lines 251 in lower metal layers M1, M2, . . . , and/or M(t-1) and the metal vias 253 in each layer in FIGS. 2B and 2C are for examples only and may be any suitable numbers. In the depicted embodiments, each of the metal lines 251 of the L-shaped section 372, the first sub seal ring 362, and the second sub seal ring 377 in lower metal layers M1, M2, . . . , and/or M(t-1) has a similar width along the X direction as the corresponding topmost metal line 251 (e.g., a metal line 251 in the metal layer Mt) directly thereabove. In some embodiments, in each of the L-shaped section 372, the first sub seal ring 362, and the second sub seal ring 377, from a top view, the metal lines 251 disposed in Ml through Mt metal layers have similar or the same dimensions and/or shape. In other embodiments, the metal lines 251 of the L-shaped section 372, the first sub seal ring 362, and the second sub seal ring 377 in each of the lower metal layers M1, M2, . . . , and/or (Mt-1) are discrete and each have smaller widths compared to the corresponding top metal line 251 directly thereabove.

The top metal line 251 of the L-shaped section 372 is a continuous metal line having an “L” shape and has similar dimensions and the same shape as the L-shaped section 372 from a top view. As depicted in FIG. 2C, the top metal line 251 of the L-shaped section 372 extends continuously into the first sub seal ring 362. In other words, the top metal line 251 of the L-shaped section 372 joins and is in direct contact with the top metal line 251 of the first sub seal ring 362. The top metal line 251 of the bridge section 366 is a continuous metal line having the same dimensions and shape as the bridge section 366 from a top view.

In an embodiment, each of the metal lines 251 of the first sub seal ring 362 and the second sub seal ring 377 is formed into a ring or a ring-like structure (such as a substantially square ring) that surrounds the circuit region 150, the assembly isolation region 250, and the CSR structures 360. In other words, each of the metal lines 251 of the first sub seal ring 362 and the second sub seal ring 377 is formed into a closed structure and extends along the edges of the area occupied by the assembly isolation region 250, the circuit region 150, and the CSR structures 360. In the present embodiment, a ring or a ring-like structure refers to a closed structure, which may be rectangular, square, substantially rectangular, substantially square, or in other polygonal shapes. In some embodiments, the outer vias 253 (the metal vias 253 that are the closest and the furthest, respectively, from the CSR structure 360 and the circuit region 150) are formed into the shape of a ring. Thus, they are also referred to as via bars. Inner vias 253 (i.e., the metal vias 253 that are disposed between the outer vias 253 from a top view) are formed into discrete vias that form a line parallel to the outer vias 253.

In some embodiments, the top metal line 251 of the L-shaped section 372 has a width W3 along the X direction, and the top metal line 251 of the first sub seal ring 362 has a width W4 along the X direction. In some embodiments, the width W3 is greater than the width W4. The top portion and the sloped portion of the L-shaped section 372 as in FIG. 2A may also have the width W3 along an R direction and the Y direction, respectively. The R direction is perpendicular to an edge of the sloped portion of the L-shaped section 372. In some embodiments, W3 and/or W4 is about 5 μm to about 12 μm. If the widths W3 and W4 are too large, it may unnecessarily increase the footprint of the L-shaped section 372 and the fabrication costs associated therewith. If the widths W3 and W4 are too small, the L-shaped section 372 may be too small to be identified during an assembly alignment process, and mechanical benefits provided by the CSR structure 360 to the seal ring 351 may be reduced. In some embodiments, a ratio of W3 to L1 (or L2) is about 0.15 to about 0.5. If the ratio of W3 to L1 (or L2) is too large, the width W3 may be too large and/or the length L1 (or L2) may be too small, and it may unnecessarily increase the footprint of the L-shaped section 372 and the costs associated therewith. If the ratio of W3 to L1 (or L2) is too small, the width W3 may be too small and/or the length L1 (or L2) may be too large, and the alignment mark 370 in the L-shaped section 372 may be too small to be identified during an assembly alignment process, and mechanical benefits provided by the CSR structure 360 to the seal ring 351 may be reduced.

The metal lines 251 and the metal vias 253 may comprise copper, copper alloys, titanium, tantalum, tungsten, cobalt, molybdenum, ruthenium, or a conductive nitride such as titanium nitride, titanium aluminum nitride, tungsten nitride, tantalum nitride, or other conductive materials, or combinations thereof, and may be formed using damascene processes, dual damascene processes, chemical vapor deposition (CVD), physical vapor deposition (PVD), atomic layer deposition (ALD), and/or other suitable processes. Each of the metal lines 251 and the metal vias 253 may include a conductive barrier layer (such as TiN or TaN) surrounding a metal core (such as copper).

In the depicted embodiment, each of the first area 376, the second arca 374, and the second sub seal ring 377 further includes dummy metal lines 254 stacked one over another in the first metal layer (M1) through the top metal layer (Mt). Although not depicted, the interior linear structure 380, interior linear structure 368, and the exterior corner structure 371 may include dummy metal lines similar as the dummy metal lines 254. Numbers of the dummy metal lines 254 in FIGS. 2B and 2C are for examples only and may be any suitable numbers. Having the dummy metal lines can reduce or eliminate process variations, such as reducing or eliminating dishing effects during CMP because the pattern density in the seal ring region 350, the assembly isolation region 250, and the circuit region 150 may be controlled to be about the same. In an embodiment, the dummy metal lines 254 in a same metal layer of the semiconductor structure 100 are separate from each other (i.e., they are not connected), with spacing among them satisfying the design rules for the manufacturing process. In the embodiment depicted in FIGS. 2B and 2C, the dummy metal lines 254 at adjacent metal layers of the semiconductor structure 100 are separate from each other. In an alternative embodiment, the dummy metal lines 254 at adjacent metal layers of the semiconductor are connected by metal vias. Alternatively, some of the dummy metal lines 254 are vertically connected and some of the dummy metal lines 254 are vertically disconnected or discrete. The dummy metal lines 254 may have similar materials as the metal lines 251. Each of the dummy metal lines 254 may include a conductive barrier layer (such as TiN or TaN) surrounding a metal core (such as copper). In some embodiments, each of the dummy metal lines 254 of the second sub seal ring 377 is formed into a ring or a ring-like structure (such as a substantially square ring) that surrounds the circuit region 150, the assembly isolation region 250, the CSR structures 360, and the first sub seal ring 362.

In an embodiment, from a top view, the dummy metal lines 254 of the first arca 376 and the second area 374 are of rectangular shapes (including long and/or short rectangles), square shapes, or other shapes. The shapes of these dummy metal lines 254 may be uniform in an embodiment. In an alternative embodiment, the shapes of the dummy metal lines 254 may be non-uniform, i.e., having mixed shapes among them. Further, the dummy metal lines 254 can be of any size as long as they meet the design rules for the manufacturing process. In some embodiments, the dummy metal lines 254 are inserted uniformly or substantially uniformly in the first area 376 and the second arca 374. In the depicted embodiments, each of the dummy metal lines 254 of the first arca 376 and the second area 374 in the lower metal layers M1, M2, . . . , and/or M(t-1) has a similar or the same width along the X direction as the corresponding top dummy metal line 254 directly thereabove. In some other embodiments, the dummy metal lines 254 of the first arca 376 and the second area 374 in the lower metal layers M1, M2, . . . , and/or (Mt-1) have different widths compared to the corresponding top dummy metal line 254 directly thereabove.

In some embodiments, each of the first sub seal ring 362 and the second sub seal ring 377 further includes an AP 264 disposed over, connected to, and electrically coupled to, the top metal line 251 (i.e., the metal line 251 in the metal layer Mt) of the first sub seal ring 362 and the second sub seal ring 377, respectively, by one or more AP vias 265. Numbers of the AP vias 265 in FIGS. 2B and 2C are for examples only and may be any suitable numbers. In some embodiments, the APs 264 and the AP vias 265 include aluminum, tungsten, some other metal or conductive material, or a combination thereof. In some embodiments, the APs 264 and the AP vias 265 include aluminum. Each of the APs 264 and/or the AP vias 265 may be formed into a shape of a ring that surrounds the circuit region 150, the assembly isolation region 250, and the CSR structures 360. Thus, the APs 264 may also be referred to as aluminum rings 264. The APs of the first sub seal ring 362 and the second sub seal ring 377 may have similar dimensions as the top metal lines 251 of the first sub seal ring 362 and the second sub seal ring 377, respectively. The APs 264 and the AP vias 265 may be formed simultaneously with the formation of bond pads (not shown) that are exposed on the top surface of circuit region 150. In addition to providing electrical connectivity to the metal lines 251, the APs 264 also prevent the components therebelow from undesirable damage, such as oxidation. Electrical access to the various components of the semiconductor seal ring region 350 is made possible through the APs 264, the AP vias 265, the metal lines 251, and the metal vias 253.

In the depicted embodiment, the L-shaped section 372 and the bridge section 366 are free of an AP overlying the top metal lines 251 thereof. In some embodiments, the top metal line 251 of the L-shaped section 372 is used as the alignment mark 370. The first area 376 and the second area 374 are free of a dummy AP or an AP overlying the dummy metal lines 254 thereof. Eliminating dummy APs in the first area 376 and the second area 374 reduces defects associated with dummy APs (e.g., a dummy AP may be incorrectly connected to an AP of the seal ring 351) while dummy metal lines 254 and/or other structures in the first area 376 and the second area 374 still provide stress release. Further, other structures of the semiconductor structure 100, such as the metal lines 251 of the bridge section 366 and the L-shaped section 372 can provide stress relief though such structures do not include APs.

In some embodiments, the semiconductor structure 100 further includes dielectric layers 210. The conductive features 218, the metal lines 251, and the metal vias 253 are embedded in dielectric layers 210. The dielectric layers 210 may include silicon oxide, silicon nitride, silicon oxynitride, low-k dielectric materials, extreme low-k (ELK) dielectric materials, or other suitable dielectric materials (for example, including silicon, oxygen, nitrogen, carbon, or other suitable isolation constituent), or combinations thereof. In some embodiments, the semiconductor structure 100 further includes a passivation layer 260 over the dielectric layers 210 and another passivation layer 262 over the passivation layer 260. The APs 264 are disposed over the passivation layer 260 and the AP vias 265 penetrate the passivation layer 260. The passivation layer 262 is disposed over the passivation layer 260 and the APs 264. The passivation layers 260 and 262 may be formed of oxides, nitrides, and combinations thereof, and may be formed of the same or different materials. In some embodiments, the passivation layers 260 and 262 are transparent or substantially transparent, such that the alignment marks 370 (such as those provided by L-shaped section 372) may be identified through the passivation layers 260 and/or 262 during an assembly alignment process. The passivation layers 260 and 262 may be deposited by a high aspect ratio process (HARP) and/or a high density plasma (HDP) CVD process.

It is understood that FIGS. 2B and 2C merely illustrate a simplified arrangement of a portion of the semiconductor structure 100. In other words, the metal lines 251, the metal vias 253, the dummy metal lines 254, the APs 264, the AP vias 265, the conductive features 218, the dielectric layers 210, and the passivation layers 260 and 262 are merely represented at a conceptual level, and their actual arrangement and configuration in the semiconductor structure 100 may be different than what is shown in FIGS. 2B and 2C.

Referring to FIGS. 3A-3C, the area A of semiconductor structure 100 in FIG. 1 is configured according to an alternative embodiment. For example, in FIGS. 3A-3C, in contrast to area A in FIGS. 2A-2C, the L-shaped section 372 (e.g., top metal line 251 thereof) is separated from seal ring 351 (e.g., top metal line 251 thereof), instead of connected thereto. In such embodiment, L-shaped section 372 can include a continuous L-shaped line 375 and two space sections 379 adjacent to two ends 381 of the continuous L-shaped line 375. The continuous L-shaped line 375 can be used as the alignment mark 370. The two space sections 379 are disposed between each of the two ends 381 of the continuous L-shaped line 375 and a respective edge of the seal ring 351. Compared to the semiconductor structure 100 in FIGS. 2A-2C, disconnecting the metal lines 251 of the L-shaped section 372 and the first sub seal ring 362 may provide additional edges for alignment, for example, the two ends 381 of the continuous L-shaped line 375 provide further alignment.

Referring to FIG. 3C, the continuous L-shaped line 375 includes the metal lines 251 of the L-shaped section 372. The top metal line 251 of the L-shaped section 372 is a continuous metal line having the same dimensions and shape as the continuous L-shaped line 375 from a top view. The space section 379 is between the continuous L-shaped line 375 and the first sub seal ring 362. In each metal layer, the space section 379 includes the dielectric layer 210 that fills the space between the metal line 251 of the L-shaped section 372 and the metal line 251 of the first sub seal ring 362. In some embodiments, a width W5 of the space section 379 is about 1 μm to about 5 μm. If W5 is too large, the continuous L-shaped line 375 (i.e., the alignment mark 370) may be too small to identify during assembly alignment processes. If W5 is too small, the two ends 381 of the continuous L-shaped line 375 may be too close to the first sub seal ring 362, and benefits of providing additional edges for alignment may be negligible. In some embodiments, a ratio of W5 to L1 (or L2) is about 0.03 to about 0.3.

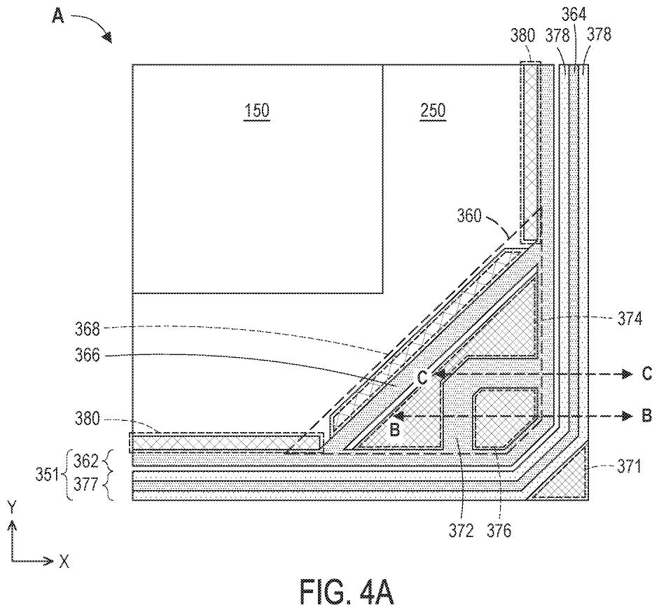

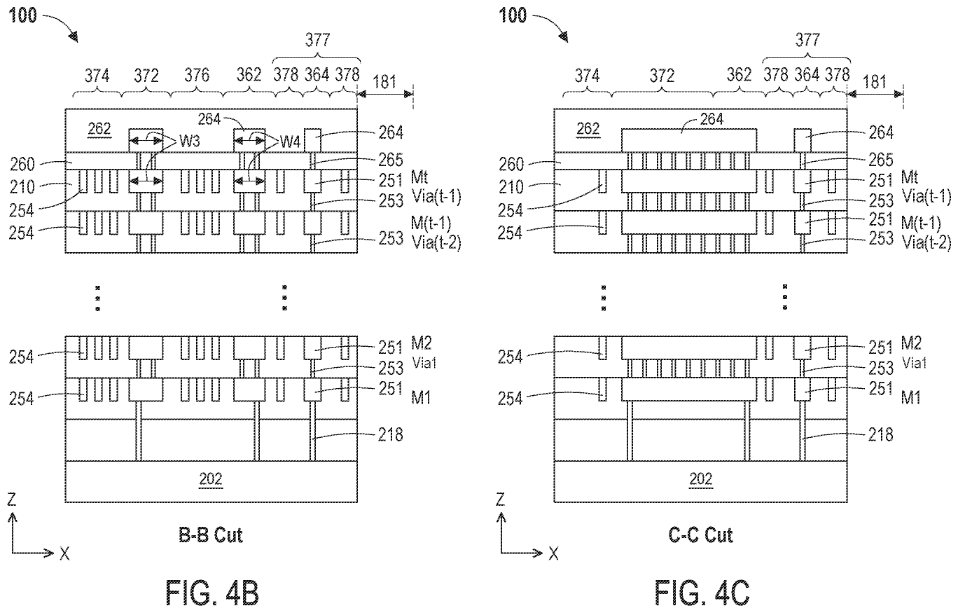

Referring to FIGS. 4A-4C, the area A of semiconductor structure 100 in FIG. 1 is configured according to another alternative embodiment. For example, in FIGS. 4A-4C, in contrast to area A in FIGS. 2A-2C, the L-shaped section 372 and the bridge section 366 cach include an AP 264 over the top metal lines 251. The AP 264 of the L-shaped section 372 can be used as the alignment mark 370 and extends between a first edge and a second edge of the AP 264 of the first sub seal ring 362. The AP 264 of the bridge section 366 extends between the first edge and the second edge of the AP 264 of the first sub seal ring 362. Referring to FIG. 4C, the AP 264 of the L-shaped section 372 is a continuous AP having similar dimensions and shape as the top metal line 251 of the L-shaped section 372. In some embodiments, the AP 264 of the L-shaped section 372 is connected to the top metal line 251 of the L-shaped section 372 by the AP vias 265. Further, in some embodiments, the L-shaped section 372 and the seal ring 351 (e.g., first sub seal ring 362 thereof) share metal lines and APs, such as top metal line 251 in the metal layer Mt and AP 264 thercover. For example, in FIG. 4C, the top metal line 251 and the AP 264 extend continuously and/or span both the L-shaped section 372 and the first sub seal ring 362. Although not depicted, the AP 264 of the bridge section 366 is a continuous AP having similar dimensions and shape as the bridge section 366 and connected to the top metal line 251 of the bridge section 366. One of the benefits of having APs 264 over the top metal lines 251 in the L-shaped section 372 and the bridge section 366 includes that, the APs 264 may protect structures therebelow (e.g., the metal lines 251 and the metal vias 253) while being used as the alignment mark 370.

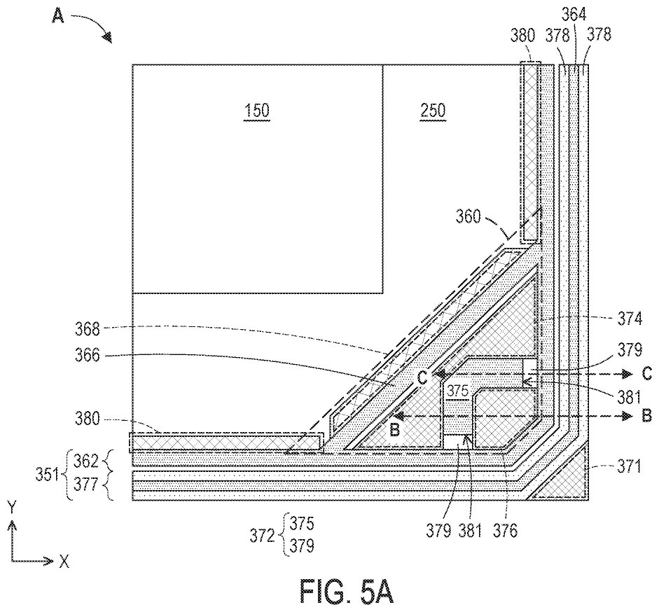

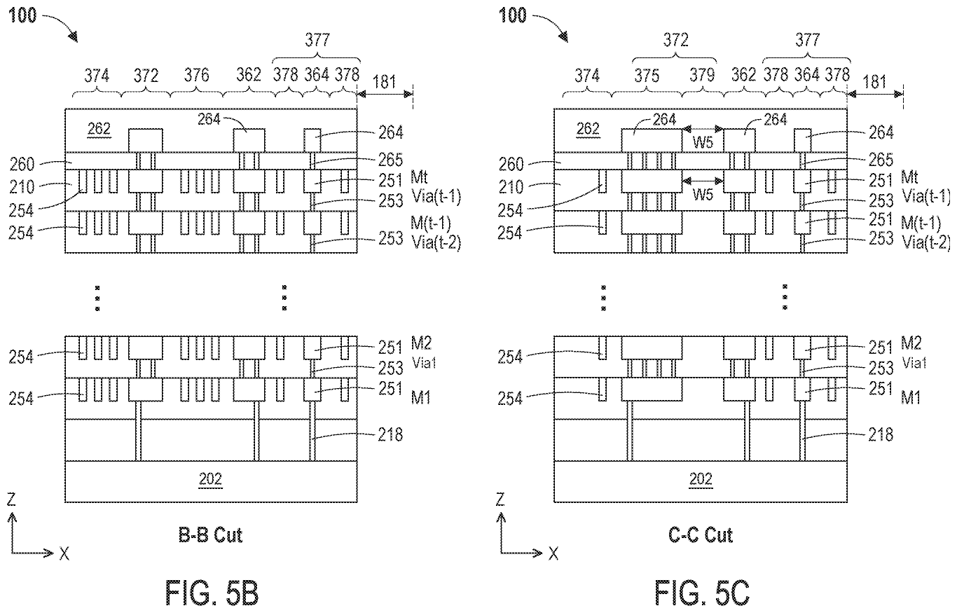

Referring to FIGS. 5A-5C, the area A of semiconductor structure 100 in FIG. 1 is configured according to yet another alternative embodiment. For example, in FIGS. 5A-5C, in contrast to area A in FIGS. 3A-3C, the L-shaped section 372 (i.e., the continuous L-shaped line 375) and the bridge section 366 each includes an AP 264 over the top metal lines 251. The AP 264 of the L-shaped section 372 can be used as the alignment mark 370 and is spaced apart from the AP 264 of the first sub seal ring 362. The AP 264 of the bridge section 366 is similar to the AP 264 of the bridge section 366 described with reference to FIGS. 4A-4C. Referring to FIG. 5C, the APs 264 of the L-shaped section 372 and the first sub seal ring 362 are separated from each other by the passivation layer 262 in space section 379 and the distance therebetween is W5. In some embodiments, the AP 264 of the L-shaped section 372 is a continuous AP connected to top metal line 251 of L-shaped section 372 and has similar dimensions and shape as the top metal line 251 of the L-shaped section 372. One of the benefits of having APs 264 over the top metal lines 251 in the L-shaped section 372 and the bridge section 366 includes that the APs 264 may protect structures below (e.g., the metal lines 251 and the metal vias 253) while being used as the alignment mark 370. Compared to the semiconductor structure 100 in FIGS. 4A-4C, disconnecting the metal lines 251 and the APs 264 of the L-shaped section 372 and the first sub seal ring 362 may provide additional edges for alignments, such as the two ends 381 of the continuous L-shaped line 375.

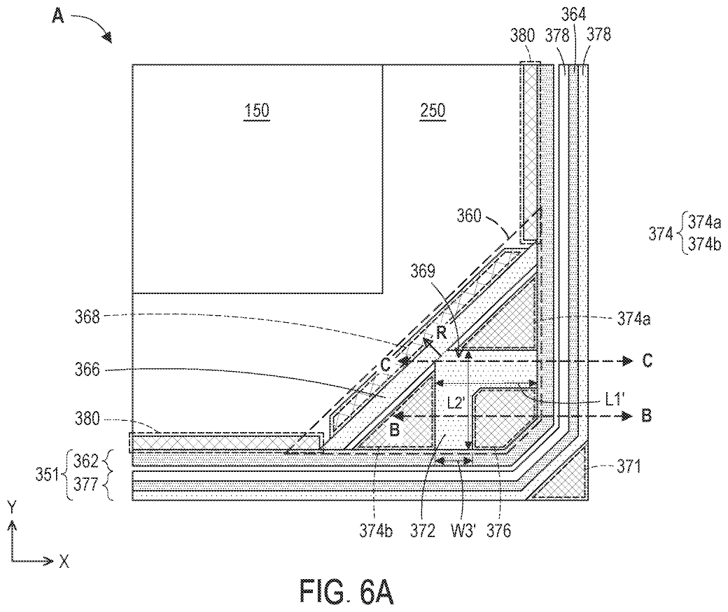

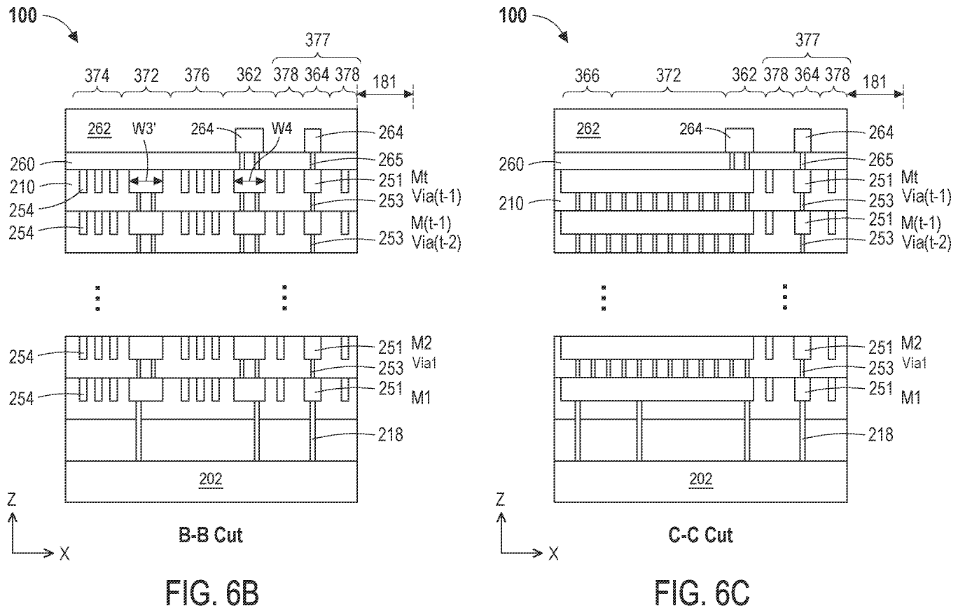

Referring to FIGS. 6A-6C, the area A of semiconductor structure 100 in FIG. 1 is configured according to yet another alternative embodiment. In FIGS. 6A-6C, in contrast to area A in FIGS. 2A-2C, the L-shaped section 372 is connected with the bridge section 366 at a joint 369 of two edges of the “L” shape. Therefore, the second arca 374 is divided by the L-shaped section 372 into two regions, such as a subregion 374a and a subregion 374b, cach having a triangular or substantially triangular shape. The L-shaped section 372 can be used as the alignment mark 370.

In some embodiments, a first length of the L-shaped section 372 along the X direction is L1', and a second length of the L-shaped section 372 along the Y direction is L2′. In some embodiments, L1' and/or L2′ is about 20 μm to about 45 μm. In some embodiments, L1' is about the same as L2′. In some embodiments, a ratio of L1' to L2′ is about 0.5 to about 2. In some embodiments, the L-shaped section 372 has a width W3′ along the X direction. In embodiments, the width W3′ is greater than the width W4 of the top metal line 251 of the first sub seal ring 362. The top portion and the sloped portion of the L-shaped section 372 as in FIG. 6A may also have the width W3′ along the R direction and the Y direction, respectively. In some embodiments, width W3′ is about 5 μm to about 15 μm. In some embodiments, a ratio of W3′ to L1' (or L2′) is about 0.15 to about 0.5. By connecting the joint 369 of the L-shaped section 372 with the bridge section 366, the lengths and widths of the L-shaped section 372 (i.e., the alignment mark 370) can be increased without increasing the footprint of the seal ring region 350. This may improve alignment mark identification during the assembly alignment process. Referring to FIG. 6C, the top metal line 251 of the L-shaped section 372 extends continuously into the bridge section 366. In other words, in such embodiments, metal lines, such as top metal line 251, may span and form a portion of L-shaped section 372, bridge section 366, and seal ring 351 (e.g., the first sub seal ring 362).

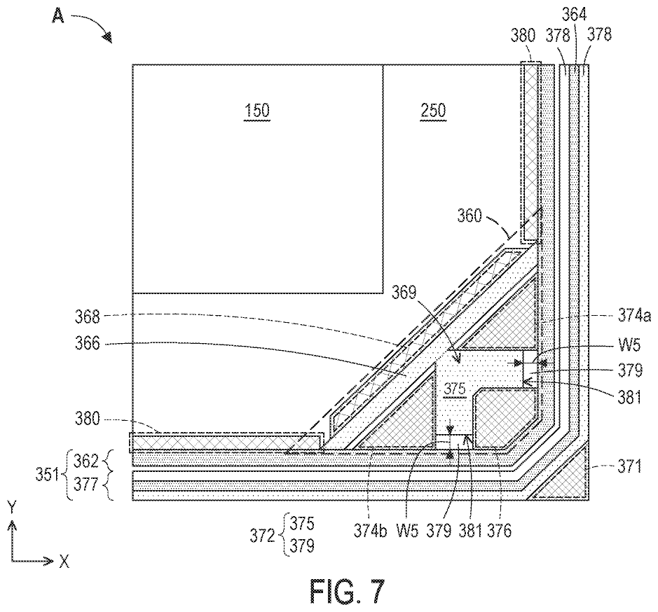

Referring to FIG. 7, the arca A of semiconductor structure 100 in FIG. 1 is configured according to yet another alternative embodiment. In FIG. 7, in contrast to arca A in FIGS. 6A-6C, the L-shaped section 372 includes continuous L-shaped line 375 and two space sections 379 adjacent to two ends 381 of the continuous L-shaped line 375, such that the continuous L-shaped line 375 is separated from the seal ring 351 by the two space sections 379, such as described with reference to FIGS. 3A-3C. Although not depicted, one having ordinary skill in the art can recognize cross-sectional structures for the embodiments disclosed herein according to the descriptions hereinabove in this disclosure.

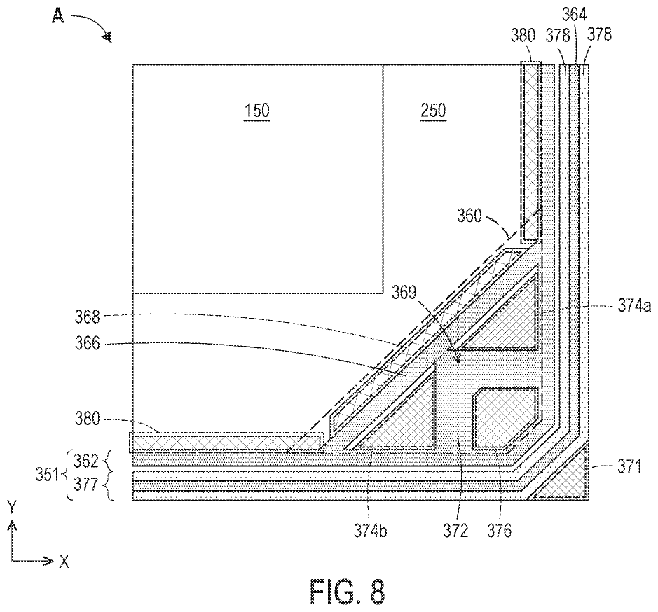

Referring to FIG. 8, the area A of the semiconductor structure 100 in FIG. 1 is configured according to yet another alternative embodiment. In FIG. 8, in contrast to area A in FIGS. 6A-6C, the L-shaped section 372 and the bridge section 366 each further include an AP 264 over the top metal lines 251. The APs 264 of the L-shaped section 372 and the bridge section 366 have similar dimensions and shapes as the top metal lines 251 of the L-shaped section 372 and the bridge section 366, respectively. Although not depicted, one having ordinary skill in the art can recognize cross-sectional structures for the embodiments disclosed herein according to the descriptions hereinabove in this disclosure.

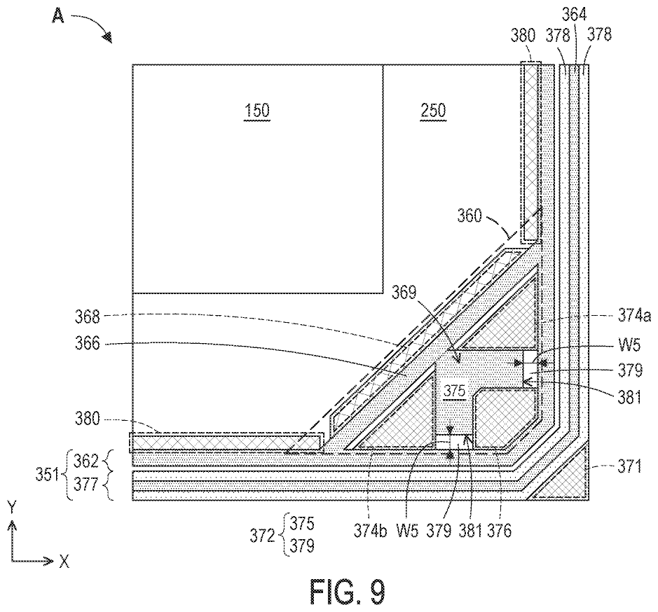

Referring to FIG. 9, the area A of the semiconductor structure 100 in FIG. 1 is configured according to yet another alternative embodiment. In FIG. 9, in contrast to the arca A of FIG. 7, the continuous L-shaped line 375 and the bridge section 366 include APs 264 over the top metal lines 251, and the APs 264 have similar dimensions and shapes as the top metal lines 251 of the continuous L-shaped line 375 and the bridge section 366, respectively. Although not depicted, one having ordinary skill in the art can recognize cross-sectional structures for the embodiments disclosed herein according to the descriptions hereinabove in this disclosure.

Although not intended to be limiting, embodiments of the present disclosure provide one or more of the following advantages. For example, the semiconductor structure disclosed herein reduces and/or avoids defects of alignment marks and seal rings by eliminating dummy conductive pads (e.g., dummy APs), and thus reducing an area consumed by dummy conductive pads, in a seal ring region. In some examples, embodiments of the present disclosure provide more edges for alignment during assembly alignment processes by separating the alignment mark (e.g., an L-shaped top metal line or an L-shaped AP) in the CSR structure from the seal ring. In some examples, embodiments of the present disclosure improve alignment by increasing the lengths and/or widths of the alignment mark without increasing footprint of the seal ring region, which can be achieved by connecting the joint of the L-shaped section with the bridge section.

In one example aspect, the present disclosure is directed to a semiconductor structure that includes a circuit region, a seal ring surrounding the circuit region, and a corner seal ring (CSR) structure at an interior corner of the seal ring. The seal ring forms a substantially rectangular periphery. The CSR structure includes a bridge section extending between a first edge and a second edge of the seal ring, an L-shaped section disposed between the seal ring and the bridge section and extending between the first edge and the second edge of the seal ring, a first area between the seal ring and the L-shaped section, and a second area between the L-shaped section and the bridge section. The seal ring includes a first top metal line and an aluminum pad (AP) disposed over and connected to the first top metal line. The L-shaped section includes a second top metal line, the second top metal line having an L-shape. The first area and the second area are free of dummy AP.

In an embodiment, the L-shaped section is free of an AP overlying the second metal line. In an embodiment, the semiconductor structure further includes a passivation layer disposed over the first top metal line and the second top metal line. In an embodiment, the second top metal line is spaced apart from the first top metal line. In an embodiment, the first top metal line has a first width, and the second top metal line has a second width greater than the first width. In an embodiment, the AP is a first AP, the L-shaped section includes a second AP disposed over and connected to the second top metal line, the bridge section includes a third top metal line and a third AP disposed over and connected to the third top metal line, the third AP is connected to the first AP, and the third top metal line is connected to the first top metal line. In an embodiment, the second AP is spaced apart from the first AP. In an embodiment, the first AP has a first width, and the second AP has a second width greater than the first width. In an embodiment, the first area and the second area each include an array of dummy top metal lines. In an embodiment, the bridge section includes a third top metal line connected to the first top metal line, and the second top metal line directly contacts the third top metal line. In an embodiment, the AP is a first AP, the seal ring is a first seal ring, and the semiconductor structure further includes a second seal ring surrounding the first seal ring. The second seal ring includes a third top metal line and a second AP disposed over and connected to the third top metal line. The third top metal line is concentric to and spaced apart from the first top metal line, and the second AP is concentric to and spaced apart from the first AP.

In another example aspect, the present disclosure is directed to a semiconductor structure that includes a substrate having a seal ring region and a circuit region, a first seal ring structure disposed in the seal ring region, a second seal ring structure disposed in a corner section of the seal ring region and connecting two edges of the first seal ring structure, and a third seal ring structure disposed between the first seal ring structure and the second seal ring structure, the third seal ring structure having an L-shape. A first arca between the first seal ring structure and the third seal ring structure and a second arca between the second seal ring structure and the third seal ring structure are free of aluminum pads (APs).

In an embodiment, the first seal ring structure is spaced apart from the third seal ring structure. In an embodiment, the first seal ring structure, the second seal ring structure, and the third seal ring structure include a first stack of metal layers, a second stack of metal layers, and a third stack of metal layers, respectively. The first area and the second area include a first stack of dummy metal layers and a second stack of dummy metal layers, respectively. The first seal ring structure includes an AP layer over the first stack of metal layers. In an embodiment, the AP layer is a first AP layer, the second seal ring structure includes a second AP layer over the second stack of metal layers, and the third seal ring structure includes a third AP layer over the third stack of metal layers. In an embodiment, the second seal ring structure and the third seal ring structure are cach free of an AP layer. In an embodiment, the second seal ring structure is connected to the first seal ring structure and the third seal ring structure is not connected to the first seal ring structure. In an embodiment, the semiconductor structure further includes a fourth seal ring structure surrounding the first seal ring structure from a top view.

In yet another example aspect, the present disclosure is directed to a semiconductor structure that includes a substrate having a seal ring region and a circuit region, a first seal ring structure disposed in the seal ring region and surrounding the circuit region, and a second seal ring structure disposed inside the corner section of the seal ring region. A portion of the first seal ring structure having a first L-shape forms a corner in a corner section of the seal ring region. The second seal ring structure has a second L-shape opposing the first L-shape. The first seal ring structure includes a first stack of metal layers and an aluminum pad (AP) layer over the first stack of metal layers. The second seal ring structure includes a second stack of metal layers. An area between the first seal ring structure and the second seal ring structure includes a stack of dummy metal layers and is free of an AP layer.

In an embodiment, the second seal ring structure is free of an AP layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

1. A semiconductor structure, comprising:
a circuit region;
a seal ring surrounding the circuit region, wherein the seal ring forms a substantially rectangular periphery; and
a corner seal ring (CSR) structure at an interior corner of the seal ring, wherein the CSR structure includes:
a bridge section extending between a first edge and a second edge of the seal ring,
an L-shaped section disposed between the seal ring and the bridge section and extending between the first edge and the second edge of the seal ring,
a first area between the seal ring and the L-shaped section,
a second area between the L-shaped section and the bridge section,
wherein the seal ring includes a first top metal line and an aluminum pad (AP) disposed over and connected to the first top metal line,
wherein the L-shaped section includes a second top metal line, the second top metal line having an L-shape, and
wherein the first area and the second area are free of dummy AP.

2. The semiconductor structure of claim 1, wherein the L-shaped section is free of an AP overlying the second metal line.

3. The semiconductor structure of claim 1, further comprising a passivation layer disposed over the first top metal line and the second top metal line.

4. The semiconductor structure of claim 1, wherein the second top metal line is spaced apart from the first top metal line.

5. The semiconductor structure of claim 1, wherein the first top metal line has a first width, and the second top metal line has a second width greater than the first width.

6. The semiconductor structure of claim 1, wherein:
the AP is a first AP;
the L-shaped section includes a second AP disposed over and connected to the second top metal line;
the bridge section includes a third top metal line and a third AP disposed over and connected to the third top metal line;
the third AP is connected to the first AP; and
the third top metal line is connected to the first top metal line.

7. The semiconductor structure of claim 6, wherein the second AP is spaced apart from the first AP.

8. The semiconductor structure of claim 6, wherein the first AP has a first width, and the second AP has a second width greater than the first width.

9. The semiconductor structure of claim 1, wherein the first area and the second area each include an array of dummy top metal lines.

10. The semiconductor structure of claim 1, wherein:
the bridge section includes a third top metal line connected to the first top metal line; and
the second top metal line directly contacts the third top metal line.

11. The semiconductor structure of claim 1, wherein the AP is a first AP, the seal ring is a first seal ring, and the semiconductor structure further comprises:
a second seal ring surrounding the first seal ring;
wherein the second seal ring includes a third top metal line and a second AP disposed over and connected to the third top metal line;
wherein the third top metal line is concentric to and spaced apart from the first top metal line; and
wherein the second AP is concentric to and spaced apart from the first AP.

12. A semiconductor structure, comprising:
a substrate having a seal ring region and a circuit region;
a first seal ring structure disposed in the seal ring region;
a second seal ring structure disposed in a corner section of the seal ring region and connecting two edges of the first seal ring structure;
a third seal ring structure disposed between the first seal ring structure and the second seal ring structure, the third seal ring structure having an L-shape; and
wherein a first area between the first seal ring structure and the third seal ring structure and a second area between the second seal ring structure and the third seal ring structure are free of aluminum pads (APs).

13. The semiconductor structure of claim 12, wherein the first seal ring structure is spaced apart from the third seal ring structure.

14. The semiconductor structure of claim 12, wherein:
the first seal ring structure, the second seal ring structure, and the third seal ring structure include a first stack of metal layers, a second stack of metal layers, and a third stack of metal layers, respectively;
the first area and the second area include a first stack of dummy metal layers and a second stack of dummy metal layers, respectively; and
the first seal ring structure includes an AP layer over the first stack of metal layers.

15. The semiconductor structure of claim 14, wherein the AP layer is a first AP layer, the second seal ring structure includes a second AP layer over the second stack of metal layers, and the third seal ring structure includes a third AP layer over the third stack of metal layers.

16. The semiconductor structure of claim 14, wherein the second seal ring structure and the third seal ring structure are each free of an AP layer.

17. The semiconductor structure of claim 12, wherein the second seal ring structure is connected to the first seal ring structure and the third seal ring structure is not connected to the first seal ring structure.

18. The semiconductor structure of claim 12, further comprising a fourth seal ring structure surrounding the first seal ring structure from a top view.

19. A semiconductor structure, comprising:
a substrate having a seal ring region and a circuit region;
a first seal ring structure disposed in the seal ring region and surrounding the circuit region, wherein a portion of the first seal ring structure having a first L-shape forms a corner in a corner section of the seal ring region;
a second seal ring structure disposed inside the corner section of the seal ring region, wherein the second seal ring structure has a second L-shape opposing the first L-shape;
wherein the first seal ring structure includes a first stack of metal layers and an aluminum pad (AP) layer over the first stack of metal layers;
wherein the second seal ring structure includes a second stack of metal layers; and
wherein an area between the first seal ring structure and the second seal ring structure includes a stack of dummy metal layers and is free of an AP layer.

20. The semiconductor structure of claim 19, wherein the second seal ring structure is free of an AP layer.
